(19) United States
(12) Patent Application Publication
(10) Pub. No.: US 2025/0043420 A1
(43) Pub. Date: Feb. 6, 2025

(54) ATOMIC LAYER DEPOSITION (ALD) WITH IMPROVED PARTICLE PREVENTION MECHANISM

(71) Applicant: Taiwan Semiconductor Manufacturing Company, Ltd., Hsinchu (TW)

(72) Inventors: Chung Hsien Liao, Hsinchu (TW); Jui-Mu Cho, Hsinchu (TW); Chien-Fang Lin, Tainan (TW)

(21) Appl. No.: 18/362,892

(22) Filed: Jul. 31, 2023

(51) Int. Cl. C23C 16/455; C23C 16/52

(52) U.S. Cl. CPC C23C 16/45544; C23C 16/52

(57) ABSTRACT

The thin film deposition system includes: a deposition chamber, a precursor source container containing a precursor source; and a precursor conduit. The precursor conduit is elongated and extends between a proximate end and a distal end, and the proximate end is coupled to an outlet of the precursor source container, and the distal end is coupled to an inlet of the deposition chamber.

### FIELD

Embodiments of the present disclosure relate generally to thin film deposition, and more particularly to atomic layer deposition (ALD).

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulting from iterative reduction of minimum feature size, which allows more components to be integrated into a given area.

While some integrated device manufacturers (IDMs) design and manufacture integrated circuits (IC) themselves, fabless semiconductor companies outsource semiconductor fabrication to semiconductor fabrication plants or foundries. Semiconductor fabrication consists of a series of processes in which a device structure is manufactured by applying a series of layers onto a substrate. This involves the deposition and removal of various thin film layers. The areas of the thin film that are to be deposited or removed are controlled through photolithography. Each of the deposition and removal processes is generally followed by cleaning as well as inspection steps. Therefore, both IDMs and foundries rely on numerous semiconductor equipment and semiconductor fabrication materials, often provided by vendors. There is always a need for customizing or improving those semiconductor equipment and semiconductor fabrication materials, which results in more flexibility, reliability, and cost-effectiveness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating an example thin film deposition system in accordance with some embodiments.

FIG. 2 is a diagram illustrating an example precursor conduit in accordance with some embodiments.

FIG. 3 is a diagram illustrating another example precursor conduit in accordance with some embodiments.

FIG. 4 is a diagram illustrating a primary valve in accordance with some embodiments.

FIG. 5 is a flowchart diagram illustrating an example method for operating a thin film deposition system in accordance with some embodiments of the disclosure.

FIG. 6 is a schematic diagram illustrating an example thin film produced by the present thin film deposition system or method.

### DETAILED DESCRIPTION OF THE DISCLOSURE

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below.” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

### Overview

Vapor deposition, such as chemical vapor deposition (CVD) and atomic layer deposition (ALD), is a powerful tool to produce thin films of materials for semiconductor device manufacturing. ALD is a thin-film deposition technique based on the sequential use of a gas-phase chemical process. ALD reaction uses two or more chemicals called precursors (sometimes also referred to as “reactants”), and these precursors react with the surface of a substrate one at a time in a sequential and self-limiting manner. A thin film is slowly deposited through repeated exposure to different precursors. Because the reaction is surface-limited, ALD creates more conformal films with well-controlled thickness than other CVD techniques do.

Generation and supply of a stable precursor vapor with a steady concentration from a condensed precursor source is critically important to the overall quality of the deposited thin film. Solid precursor sources are typically stored in a container. When the container is heated, heat is transferred to the solid precursor sources, generating precursor vapor that is delivered to a deposition chamber. The precursor vapor is delivered to the deposition chamber through a precursor conduit (sometimes also referred to as a “precursor pipe”).

The precursor conduit sometimes has a multi-segment design. The multi-segment design is based on fluid dynamics to facilitate the delivery of precursor vapor from the container to the deposition chamber. The multi-segment precursor conduit includes multiple segments. A lower end of a first vertical segment is coupled to a proximate end of a horizontal segment, and a distal end of the horizontal segment is coupled to a lower end of a second vertical segment. Therefore, the first vertical segment, the horizontal segment, and the second vertical segment form a “U” shape structure, which can facilitate the delivery of precursor vapor based on fluid dynamics. The upper end of the first vertical segment is coupled, directly or indirectly to the container, and the upper end of the second vertical segment is coupled, directly or indirectly to the deposition chamber.

However, it has been observed that residual precursor vapor contained in the precursor conduit after the ALD process is completed may cause the deposition of the precursor itself and particle deposition in the precursor conduit. The precursor has a relatively large molecular mass as compared to, for example, a carrier gas such as argon gas, which will reinforce the deposition of the precursor at the multi-segment precursor conduit due to gravity. On the other hand, the multi-segment precursor conduit increases the overall length of the precursor conduit, thereby increasing the volume of residual precursor vapor. When the ALD process is completed, the deposition chamber is opened. Accordingly, the precursor conduit is exposed to the atmosphere. Particles may be formed as a result of the reactions between the precursor vapor and chemicals in the atmosphere. These particles are subsequently condensed and deposited on the inner surface of the precursor conduit. Although these particles are deposited on the inner surface, they may evaporate and enter the deposition chamber, thereby introducing undesired particles in the deposition chamber. As a result, the quality of the film to be deposited is compromised, which may lead to compromised device performance or even device failure.

In accordance with some aspects of the disclosure, a thin film deposition system is provided. The thin film deposition system includes, among other components, a deposition chamber, a precursor source container containing a precursor source, and a precursor conduit coupled between the precursor source container and the deposition chamber. In one embodiment, the precursor conduit is elongated and extends between a proximate end and a distal end. The proximate end is coupled to an outlet of the precursor source container, and the distal end is coupled to an inlet of the deposition chamber. The precursor conduit extends horizontally or substantially horizontally.

By replacing the “U” shape segments used in the multi-segment precursor conduit with a continuous elongated segment, the deposition of the precursor vapor in the “U” shape segments can be avoided, and the overall length of the precursor conduit is minimized, thereby reducing the volume of the residual precursor vapor that remains in the precursor conduit 144 after the ALD process is completed. As a result, particle generation is mitigated.

In addition, a primary valve may be installed at the precursor conduit. The primary valve is switched off when a semiconductor fabrication process such as an ALD process performed in the deposition chamber is completed. A supplemental carrier gas can also be added to the precursor conduit in some embodiments. Accordingly, the precursor conduit is not in gas communication with the atmosphere, thereby preventing the atmosphere from entering the precursor conduit to react with the precursor vapor. Therefore, particle deposition in the precursor conduit can be mitigated or avoided.

### Example Thin Film Deposition System with Improved Particle Prevention Mechanism

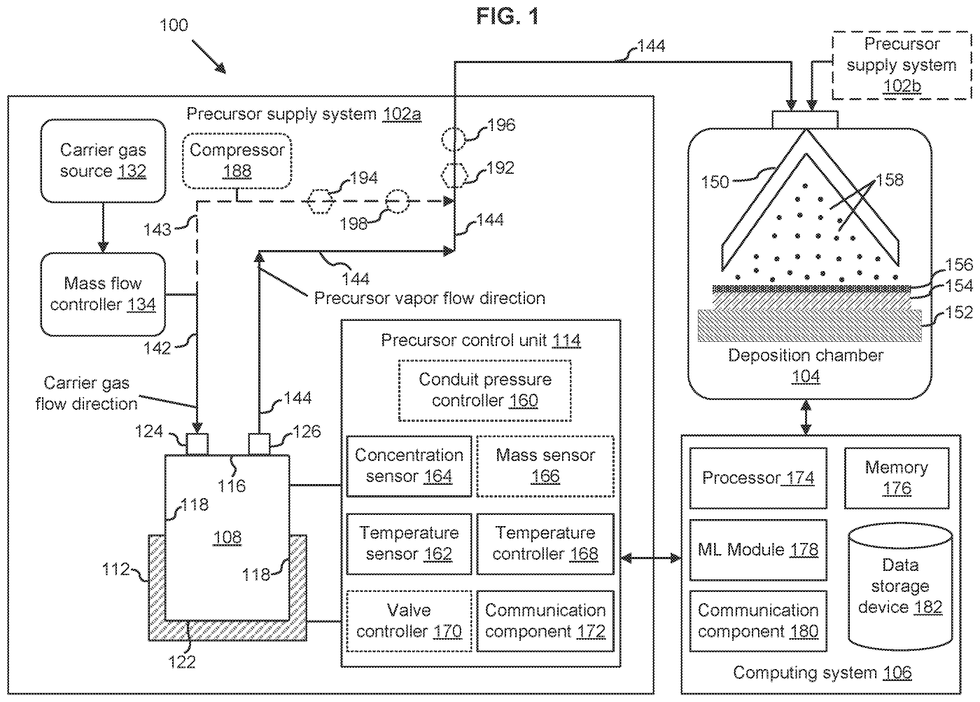

FIG. 1 is a diagram illustrating an example thin film deposition system 100 in accordance with some embodiments. It should be understood that the thin film deposition system 100 and various components thereof are exemplary rather than limiting. One of ordinary skill in the art would recognize many variations, modifications, and alternatives within the contemplation of the present disclosure. It should also be understood that FIG. 1 is not drawn to scale.

The thin film deposition system 100 is generally used in semiconductor manufacturing processes, particularly vapor deposition processes, in which the target material goes from a condensed phase (e.g., a solid phase, a semi-solid phase, or a liquid phase) to a vapor phase and then back to a thin film condensed phase on a substrate. Non-limiting examples of the thin film deposition described herein include physical vapor deposition (PVD), chemical vapor deposition (CVD), metalorganic chemical vapor deposition (MOCVD), atomic layer deposition (ALD), and vapor phase epitaxy (VPE), and variations or modifications thereof. Although ALD is discussed as an example frequently throughout the disclosure, it should be understood that the techniques discussed herein are generally applicable to various thin film deposition systems 100.

In the illustrated example of FIG. 1, a thin film deposition system 100 includes, among other components, at least one precursor supply system 102 (e.g., precursor supply system 102a, precursor supply system 102b, . . . , collectively as 102), a deposition chamber 104, and a computing system 106. The precursor supply system 102 is configured to generate and supply a precursor vapor or a gaseous precursor from a precursor source (e.g., precursor source A) to the deposition chamber 104. The deposition chamber 104 is generally configured to receive the precursor vapor, which is allowed to undergo chemical or physical interaction with the surface of a substrate 154 placed in the deposition chamber 104, thereby forming a layer (or a thin film) 156 of the precursor source in a condensed phase on the substrate 154. The computing system 106 is in electrical communication with the at least one precursor supply system 102 and/or the deposition chamber 104 and configured to receive real-time signals of operational parameters or operational characteristics and to transmit real-time instructions to the at least one precursor supply system 102 and/or the deposition chamber to the guide operation of the thin film deposition system 100.

In one example, the precursor source is pentakis-(DiMethylAmido) Tantalum (V) (PDMAT) in a powder form used to form a Ta-containing thin film in an ALD process. The PDMAT vapor may have a stable concentration in the precursor source container with a deviation of less than 20%, or less than 10%, or less than 5%, from the target PDMAT vapor concentration. In some implementations, the target PDMAT vapor concentration for deposition of a TaN thin film is from about 0.0002 to about 0.002 M, or from about 0.0005 to about 0.0015 M, or from about 0.0008 to about 0.001 M. In some implementations, the generated PDMAT vapor has a mono-dispersed particle size distribution with a content of clusters or aggregates less than about 20%, or less than about 15%, or less than about 10%, or less than about 5%. Other non-limiting examples of the precursor source include Hfl₄, Al(OC₃H₇)₃, Pb(OC(CH₃)₃)₂. Zr(OC(CH₃)₃)₄, Ti(OCH(CH₃)₂)₄, Ba(OC₃H₇)₂, Sr(OC₃H₇)₂, RuCp₂, WCl₅, and the like.

In some implementations, each of the at least one precursor supply system 102 includes, a precursor source container 108 configured to store a precursor source therein and generate a precursor vapor from the precursor source to be supplied to the deposition chamber 104. The precursor source container 108 can be of any desirable shape or size. For example, the precursor source container 108 is cylindrical in shape and sized to fit within the existing space of a fabrication area. The precursor source container 108 includes a top wall 116, a side wall 118, and a bottom wall 122. The side wall 118 circumferentially connects the top wall 116 and the bottom wall 122, defining an interior space to store the precursor source and the precursor vapor generated from the precursor source. The precursor source container 108 further includes an inlet 124 and an outlet 126 separately mounted on the top wall 116. The inlet 124 is configured to allow introduction of a carrier gas into the precursor source container 108. The outlet 126 is configured to allow exit of a precursor vapor generated in the precursor source container 108.

In some implementations, the precursor supply system 102 further includes a heating element 112 in heat communication with the precursor source container 108. The heating element 112 is configured to generate heat from a heat source and irradiate heat toward at least a portion of an exterior surface of the precursor source container 108. The heating element 112 may be in contact or proximity with at least a portion of the top wall 116, at least a portion of the bottom wall 122, or at least a portion of the side wall 118, or any combinations thereof. Non-limiting examples of the heating element 112 include an electrical heat source, a furnace, an infrared heat source, a heat tape, or any combinations thereof. The heat transferred into the interior space of the precursor source container 108 promotes evaporation or sublimation of the precursor source or otherwise transforms at least a portion of the precursor source from a condensed matter phase into a gaseous phase.

In some implementations, the precursor supply system 102 further includes a carrier gas source 132 and a mass flow controller (MFC) 134. The carrier gas source 132 is configured to provide a carrier gas that flows into the MFC 134. The carrier gas source 132 may be a vessel, such as a gas storage tank, that is located either locally to the precursor source container 108 or else may be located remotely from the precursor source container 108. The carrier gas may be an inert gas or other gas that does not react with the precursor source or other materials within the thin film deposition system 100. For example, the carrier gas may be argon (Ar), helium (He), nitrogen (N₂), hydrogen (H₂), any combinations thereof, and so on, although any other suitable carrier gas may alternatively be utilized.

The mass flow controller (MFC) 134 is in gas communication with the carrier gas source 132 and the inlet 124 of the precursor source container 108. The MFC 134 is configured to control the flow of the carrier gas to the precursor source container 108 through conduit 142 and, eventually, to the deposition chamber 104, thereby also helping to control the pressure within the precursor source container 108 and the deposition chamber 104. The MFC 134 may be, for example, a proportional valve, a modulating valve, a needle valve, a pressure regulator, or any combinations thereof, and so on. The carrier gas introduced into the precursor source container 108 is further mixed with the evaporated precursor source to form a precursor vapor or a gaseous precursor.

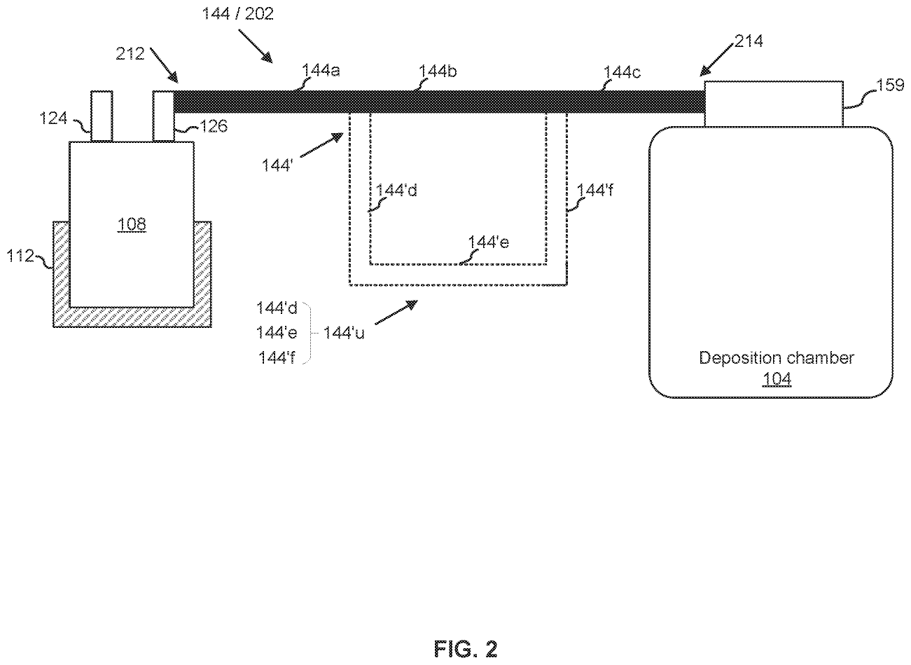

In the example shown in FIG. 1, the outlet 126 of the precursor source container 108 is in gas communication with the deposition chamber 104 through a precursor conduit 144. As will be discussed below with reference to FIG. 2, unlike a multi-segment precursor conduit, the precursor conduit 144 has a straight-segment design, which can reduce the deposition of the precursor and prevent particle generation. Although the precursor conduit 144 that is shown in FIG. 1 has a certain path with multiple segments, it should be understood that the precursor conduit 144 is schematically shown in FIG. 1 and does not represent the actual geometries thereof. Instead, FIG. 2 illustrates an example geometry of the precursor conduit 144.

In the example shown in FIG. 1, the precursor supply system 102 further includes a precursor control unit 114 in operable and controllable communication with the precursor source container 108. The precursor control unit 114 is configured to detect, monitor, and/or control at least one real-time operational parameter or characteristic of the precursor supply system 102a. The real-time operational parameters or characteristics include but are not limited to quantity, temperature, concentration, flow rate, pressure, and so on.

In the example shown in FIG. 1, the precursor control unit 114 includes, among other components, a temperature sensor 162, a concentration sensor 164, a temperature controller 168, and a communication component 172. The precursor control unit 114 may further include a conduit pressure controller, a mass sensor 166, and a valve controller 170 in other embodiments, which will be discussed below.

The temperature sensor 162 is configured to detect and monitor the temperature of the precursor source container 108. The concentration sensor 164 is configured to detect and monitor the precursor vapor concentration in the precursor source container 108. The temperature controller 168 is operably connected to the heating element 112 and is configured to control the heating element 112 and adjust the temperature of the precursor source container in situ during operation.

The mass sensor 166, which is included in some embodiments, is configured to detect and monitor an unconsumed quantity (or weight) of the precursor source remaining in the precursor source container 108. Although the temperature sensor 162, the concentration sensor 164, and the mass sensor 166 are schematically illustrated to be located in the precursor control unit 114, it should be understood that they may be mounted inside, in contact with, or in close proximity to the precursor source container 108 in other embodiments.

The communication component 172 is configured to transmit signals of the real-time operational parameters or characteristics, such as the detected temperature, the detected concentration of the precursor vapor, and/or the detected unconsumed quantity of the precursor source to the computing system 106 in situ during operation. The communication component 172 is further configured to receive one or more instructions from the computing system 106 to guide the operation of the precursor supply system 102 in situ. In some implementations, the instruction has a real-time temperature adjustment signal based on a pre-established operation model for maintaining the precursor vapor concentration in a target range, and the temperature controller 168 controls the heating element 112 in situ based on the real-time temperature adjustment signal to maintain the precursor vapor concentration in the target range.

In the illustrated example of FIG. 1, the deposition chamber 104 includes, among other components, a showerhead 150, a substrate support 152 operable to support or accommodate a substrate 154. The showerhead 150 may be utilized to disperse the chosen precursor vapor into the deposition chamber 104 and may be designed to evenly disperse the precursor source in order to minimize undesired process conditions that may arise from uneven dispersal. In some implementations, the showerhead 150 may have a circular design with openings dispersed evenly around the showerhead 150 to allow for the dispersal of the desired precursor source into the deposition chamber 104.

However, as one of ordinary skill in the art will recognize, the introduction of precursor vapor(s) into the deposition chamber 104 through a single showerhead 150 or through a single point of introduction as described above is intended to be illustrative only and is not intended to be limiting to the embodiments. Any number of separate and independent showerheads 150 or other openings to introduce precursor sources into the deposition chamber 104 may alternatively be utilized. All such combinations of showerheads and other points of introduction are fully intended to be included within the scope of the embodiments.

The deposition chamber 104 may receive the desired precursor vapor(s) and expose the precursor source material(s) of the precursor vapor(s) to the substrate 154, and the deposition chamber 104 may be any desired shape that may be suitable for dispersing the precursor source material(s) and contacting the precursor source material(s) with the substrate 154. In some implementations, the deposition chamber 104 has a cylindrical side wall and a bottom. However, the deposition chamber 104 is not limited to a cylindrical shape, and any other suitable shape, such as a hollow square tube, an octagonal shape, or the like, may alternatively be utilized. Furthermore, the deposition chamber 104 may be surrounded by a housing (not shown) made of material that is inert to the various process materials. As such, while the housing may be any suitable material that can withstand the chemistries and pressures involved in the deposition process, in some implementations the housing may be steel, stainless steel, nickel, aluminum, alloys of these, combinations of these, and the like.

Within the deposition chamber 104, the substrate 154 may be placed on a substrate support 152 in order to position and control the substrate 154 during the deposition process. The substrate support 152 may include heating mechanisms in order to heat the substrate 154 during the deposition process. Furthermore, while a single substrate support 152 is illustrated in FIG. 1, any number of substrate support 152 may additionally be included within the deposition chamber 104.

Additionally, the deposition chamber 104 and the substrate support 152 may be part of a cluster tool system (not shown). The cluster tool system may be used in conjunction with an automated handling system (e.g., an automated transfer robot) in order to position and place the substrate 154 into the deposition chamber 104 prior to the deposition process, position and hold the substrate 154 during the deposition process and remove the substrate 154 from the deposition chamber 104 after the deposition process. The deposition chamber 104 may also include an exhaust outlet (not shown) for exhaust gases to exit the deposition chamber 104.

In the illustrated example of FIG. 1, the computing system 106 includes, among other components, a processor 174, a memory 176, a machine learning (ML) module, a communication component 180, and a data storage device 182. The computing system 106 is generally configured to, among other functions, receive signals from the precursor control unit 114, process the signals, calculate a real-time adjustment value of an operational parameter or characteristic, transform the real-time adjustment value to an adjustment signal, and transmit the adjustment signals to the precursor control unit 114. The processor 174 is configured to process and analyze signals and execute instructions saved in the memory 176. The memory 176 is configured to store temporary variables or other intermediate information during the signal processing conducted by the processor 174.

The machine learning module 178 has a machine learning training algorithm configured to establish and improve an operational model for at least one operational parameter and/or a relationship between or among multiple operational parameters. The operational model may be trained by the machine learning module 178 based on a priori data generated from prior operations, with respect to a certain type of precursor source and/or in a certain type of precursor source container. The pre-established operation model generated by the machine learning module 178 can be used as a standard or reference for the processor to (1) determine whether an operational parameter is deviated from the standard or deviated from a target value or range based on the standard; (2) calculate the deviation value; (3) determine whether a real-time adjustment of the operational parameter is needed; and (4) determine the real-time adjustment value. During the operation of the thin film deposition system 100, if a real-time adjustment is needed, the computing system 106 will instantaneously transmit a real-time adjustment signal to the precursor control unit 114 in situ through, for example, the communication component 180 of the computing system 106 and the communication component 172 of the precursor control unit 114.

In some implementations, the pre-established operation model includes a mathematical profile describing the relationship between two operational parameters. The precursor control unit 114, in response to the received instruction, will adjust the operational parameter instantaneously to a target value or range. The data storage device 182 is configured to store any information related to the operation of the thin film deposition system 100, such as the real-time operational parameters or the pre-established operational model.

In some implementations, the computing system 106 is further in communication with a database through, for example, the communication component 180. The database may store any information related to the operation of the thin film deposition system 100, such as the real-time operational parameters or the pre-established operational model. The database may further store datasets (e.g., training datasets, testing datasets, etc.) accessible to the machine learning module 178, and the machine learning module 178 can be trained and tested based on these datasets accordingly.

In some implementations, the thin film deposition system 100 is an ALD system or configured to perform an ALD process. The ALD system may include at least 2, at least 3, at least 4, or at least 5 precursor supply systems configured to supply different precursor sources, respectively. The ALD system can be used to, for example, produce a variety of complex metal-containing compounds, such as metal oxides, metal nitrides, or other compounds having many main group metal elements and transition metal elements, such as aluminum, barium, cerium, dysprosium, hafnium, lanthanum, niobium, silicon, strontium, tantalum, titanium, tungsten, yttrium, zinc, and zirconium.

In the example shown in FIG. 1, the thin film deposition system 100 includes at least two precursor supply systems 102a and 102b. The precursor supply system 102b is in gas communication with the deposition chamber 104 and is configured to generate and supply a precursor vapor B from a precursor source B to the deposition chamber 104. The precursor supply system 102b may have a similar or a different configuration compared with the precursor supply system 102a.

In one example implementation of the ALD system, the precursor vapors respectively from the precursor sources A and B are sequentially applied to the substrate in the deposition chamber with each pulse of precursor vapors separated by a purge. Each application of the precursor is intended to result in up to a single monolayer of the precursor source being deposited on the surface. These monolayers are formed because of the self-terminating surface reactions between the precursors and surface. In a particular implementation, the precursor source A supplied by the precursor supply system 102a is PDMAT; and the precursor source B supplied by the precursor supply system 102b is ammonia. The PDMAT vapor and ammonia vapor are supplied to the deposition chamber 104 in a sequential and alternating manner to allow for growing TaN thin film on a substrate according to the following mechanism:

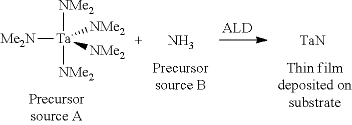

It should be understood that other Ta-containing thin films could also be produced by the present thin film deposition system using PDMAT or equivalent thereof as the precursor source. Non-limiting examples of the Ta-containing thin films include TaNₓ, TaOₓ, TaCₓ, TaₓAl_{y}N_{z}, TaₓAl_{y}C_{w}N_{z}, and so on. The Ta-containing thin films may be used as, among others, barrier layer, resistor, capacitor, or other functional components for semiconductor devices.

FIG. 2 is a diagram illustrating an example precursor conduit 144 in accordance with some embodiments. It should be understood that FIG. 2 is not drawn to scale. Components that are identical or similar to counterpart components shown in FIG. 1 are not repeated. In the example shown in FIG. 2, the precursor conduit 144 is elongated and straight and extends between a proximate end 212 and a distal end 214. The proximate end 212 is coupled to the outlet 126 of the precursor source container 108; the distal end 214 is coupled to the inlet 159 of the deposition chamber 104.

The precursor conduit 144 has an elongated section 202 (in the example shown in FIG. 2, the elongated section 202 is the precursor conduit 144). The elongated section 202 can be considered as being comprised of three segments 114a, 114b, and 114c, from the proximate end 212 to the distal end 214. The segments 114a, 114b, and 114c are continuous, and they are separated simply for the comparison with a multi-segment precursor conduit, as discussed above.

An example of multi-segment precursor conduit 144′ is shown in dashed lines in FIG. 2 for comparison. In contrast to the elongated section 202, the multi-segment precursor conduit 144′ can be considered as being comprised of segments 144a, 114c, 144′d, 144′e, and 144′f. In other words, the multi-segment precursor conduit 144′ can be considered as being comprised of segments 144a, 114c, and the “U” shape segments 144′u.

By replacing the “U” shape segments 144′u used in the multi-segment precursor conduit 144′ with the segment 144b, which is straight, the deposition of the precursor vapor in the “U” shape segments 144′u can be avoided. Since the elongated section 202 extends in a horizontal plane, the impact of gravity is mitigated, thereby reducing the accumulation of the precursor vapor. In addition, by replacing the “U” shape segments 144′u used in the multi-segment precursor conduit 144′ with the segment 144b, which is straight, the overall length of the elongated section 202 is minimized, thereby reducing the volume of the residual precursor vapor that remains in the precursor conduit 144 after the ALD process is completed. As a result, particle generation is mitigated.

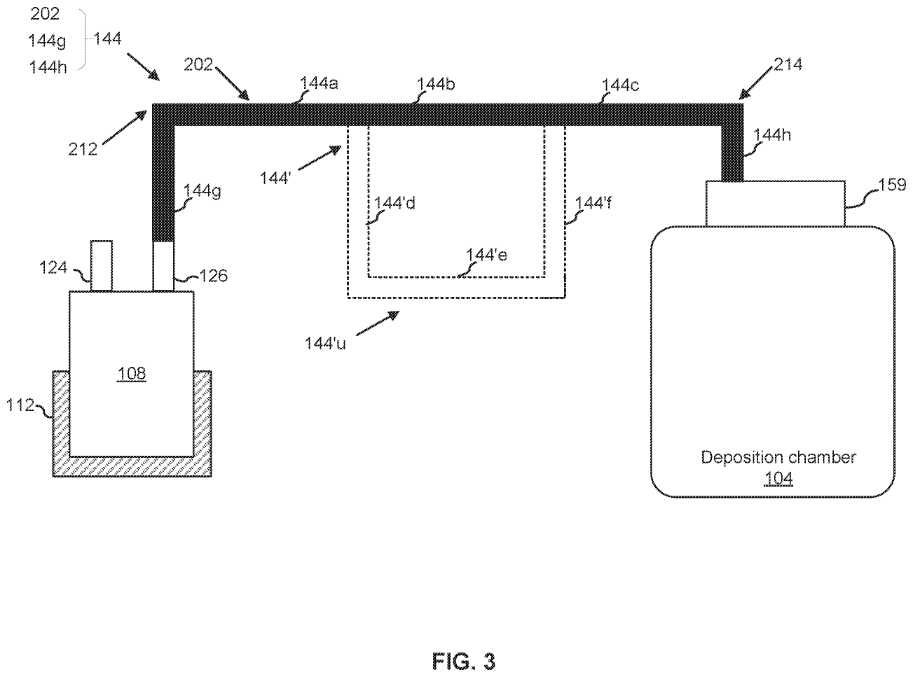

FIG. 3 is a diagram illustrating another example precursor conduit 144 in accordance with some embodiments. FIG. 3 is identical to FIG. 2 except that the precursor conduit 144 includes more than the elongated section 202. In the example shown in FIG. 3, the precursor conduit 144 includes a proximate interconnect segment 144g, the elongated section 202, and a distal interconnect segment 144h. The proximate interconnect segment 144g is coupled between the outlet 126 of the precursor source container 108 and the proximate end 212 of the elongated section 202. The distal interconnect segment 144h is coupled between the inlet 159 of the deposition chamber 104 and the distal end 214 of the elongated section 202.

Likewise, by replacing the “U” shape segments 144′u used in the multi-segment precursor conduit 144′ with the segment 144b, which is straight, the deposition of the precursor vapor in the “U” shape segments 144′u can be avoided. Since the elongated section 202 extends in a horizontal plane, the impact of gravity is mitigated, thereby reducing the accumulation of the precursor vapor. In addition, by replacing the “U” shape segments 144′u used in the multi-segment precursor conduit 144′ with the segment 144b, which is straight, the overall length of the elongated section 202 is minimized, thereby reducing the volume of the residual precursor vapor that remains in the precursor conduit 144 after the ALD process is completed. As a result, particle generation is mitigated.

Although both the proximate interconnect segment 144g and the distal interconnect segment 144h are shown in FIG. 3, it should be understood that only one of them may be present in other embodiments. Moreover, the proximate interconnect segment 144g may extend above the elongated section 202 in other embodiments. Likewise, the distal interconnect segment 144h may extend above the elongated section 202 in other embodiments. One of ordinary skill in the art would recognize many variations, modifications, and alternatives.

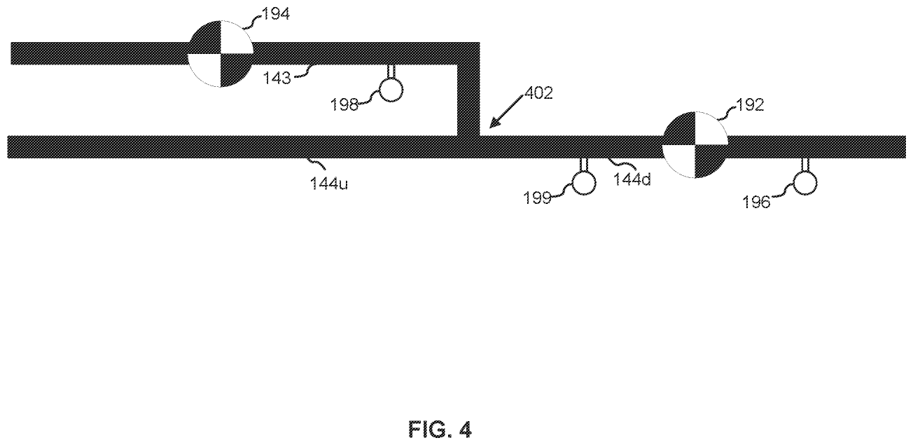

FIG. 4 is a diagram illustrating a primary valve 192 in accordance with some embodiments. In the example shown in FIG. 4, the precursor conduit 144 is coupled with a supplemental carrier gas conduit 143 at a joint 402. The section of the precursor conduit 144 at the upstream side of the joint 402 is an upstream section 144u. The section of the precursor conduit 144 at the downstream side of the joint 402 is a downstream section 144d.

The primary valve 192 is installed at the downstream section 144d. The primary valve 192 is configured to be switched off (i.e., cutting off the flow of the precursor vapor) after the ALD process is completed. As a result, the precursor conduit 144 is not in gas communication with the atmosphere after the ALD process is completed, thereby preventing the atmosphere from entering the precursor conduit 144 to react with the precursor vapor. Therefore, particle deposition in the precursor conduit 144 can be mitigated or avoided.

In one example, the primary valve 192 is a solenoid valve. The solenoid valve may convert electrical energy to mechanical energy, using an electromagnet formed from a coil of wire. The magnetic field created from electric current is used to create linear motion. The linear motion then actuates an electrical switch. The primary valve 192 may be controlled by the valve controller 170 shown in FIG. 1, in response to, for example, instructions received from the computing system 106. It should be understood that other types of valves can be used as the primary valve 192 in other embodiments.

In the example shown in FIG. 4, the supplemental carrier gas conduit 143 is coupled to the precursor conduit 144. As a result, a supplemental carrier gas is added to the precursor conduit 144, increasing the pressure at the upstream side of the primary valve 192. When the pressure at the upstream side of the primary valve 192 is higher than the pressure of the atmosphere, the flow in the precursor conduit 144 becomes unidirectional. The precursor vapor can pass through the primary valve 192 due to the relatively high pressure, while the atmosphere cannot pass through the primary valve 192 due to the relatively low pressure. As such, the atmosphere is prevented from entering the precursor conduit when the ALD process is completed. Since the carrier gas is readily available, the addition of the carrier gas does not add significant additional cost. The addition of the carrier gas can be further regulated or controlled by a secondary valve 194.

Likewise, the secondary valve 194 may be controlled by the valve controller 170 shown in FIG. 1, in response to, for example, instructions received from the computing system 106. It should be understood that solenoid valves or other types of valves can be used as the secondary valve 194 in other embodiments.

In some embodiments and as shown in FIG. 4, at least two pressure sensors 198 and 196 can be used to measure, detect, and monitor the pressure in the supplemental carrier gas conduit 143 and at the downstream side of the primary valve 192, respectively. When the pressure measured by the pressure sensor 198 is higher than the pressure measured by the pressure sensor 196, the pressure at the upstream side of the primary valve 192 (having the contribution of both the carrier gas and the precursor vapor) is higher than the pressure at the downstream side of the primary valve 192. Therefore, the atmosphere is prevented from entering the precursor conduit 144 when the ALD process is completed.

Another pressure sensor 199 may be used in addition to the pressure sensors 198 and 196. The pressure sensor 199 measures, detects, and monitors the pressure at the upstream side of the primary valve 192. When the pressure measured by the pressure sensor 199 is lower than the pressure measured by the pressure sensor 196, the pressure at the upstream side of the primary valve 192 is lower than the pressure at the downstream side of the primary valve 192. Therefore, the atmosphere may enter the precursor conduit 144 when the ALD process is completed. As a remedial measure, a compressor 188 may operate to or be configured to increase the pressure of the supplemental carrier gas in the supplemental carrier gas conduit 143, in response to instructions received from the conduit pressure controller 160 shown in FIG. 1. In another embodiment, the pressure in the supplemental carrier gas conduit 143 can be increased by the MFC 134.

It should be understood that the supplemental carrier gas conduit 143, the compressor 188 are optional. One of ordinary skill in the art would recognize many variations, modifications, and alternatives.

### Example Method for Operating a Thin Film Deposition System

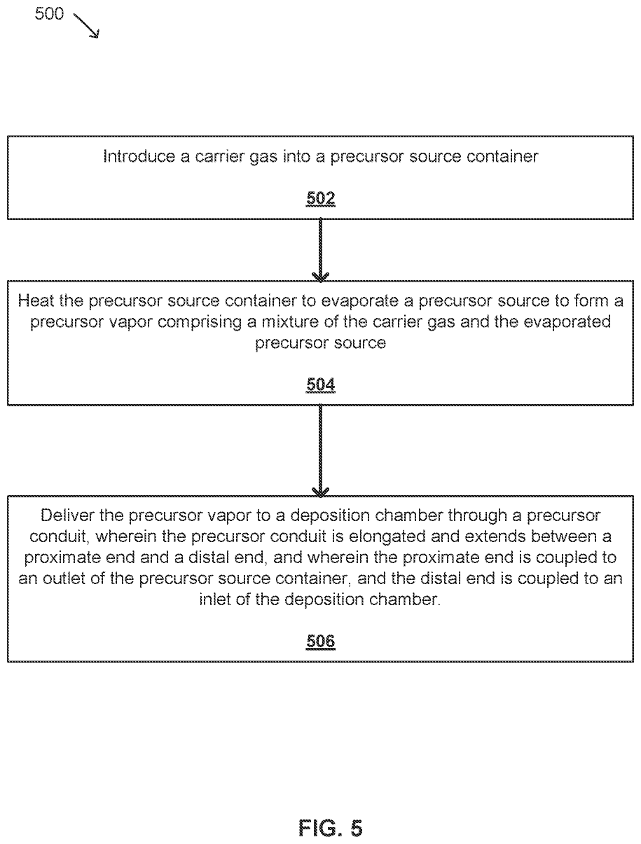

FIG. 5 is a flowchart diagram illustrating an example method for operating a thin film deposition system in accordance with some embodiments of the disclosure. In the example shown in FIG. 5, the method 500 includes operations 502, 504, and 506. Additional operations may be performed.

At operation 502, a carrier gas is introduced into a precursor source container (e.g., the precursor source container 108 shown in FIG. 1).

At operation 504, the precursor source container is heated to evaporate the precursor source to form a precursor vapor comprising a mixture of the carrier gas and the evaporated precursor source.

At operation 506, the precursor vapor is delivered to a deposition chamber (e.g., the deposition chamber 104 shown if FIG. 1) through a precursor conduit (e.g., the precursor conduit 144 shown in FIG. 2). The precursor conduit is elongated and extends between a proximate end (e.g., the proximate end 212 shown in FIG. 2) and a distal end (e.g., the distal end 214 shown in FIG. 2). The proximate end is coupled to an outlet (e.g., the outlet 126 shown in FIG. 2) of the precursor source container, and the distal end is coupled to an inlet (e.g., the inlet 159 shown in FIG. 2) of the deposition chamber.

The method may include other operations. For example, a layer resulting from the precursor source is deposited on a substrate (e.g., the substrate 154 shown in FIG. 1) in the deposition chamber. In one example, the precursor source is pentakis(DiMethylAmido)Tantalum (V) (PDMAT). As another example, a primary valve (e.g., the primary valve 192 shown in FIG. 4) installed at the precursor conduit is switched off after the deposition is completed. As yet another example, a supplemental carrier gas is introduced to the precursor conduit through a supplemental carrier gas conduit (e.g., the supplemental carrier gas conduit 143 shown in FIG. 4) coupled to the precursor conduit.

### Example Thin Film Deposited

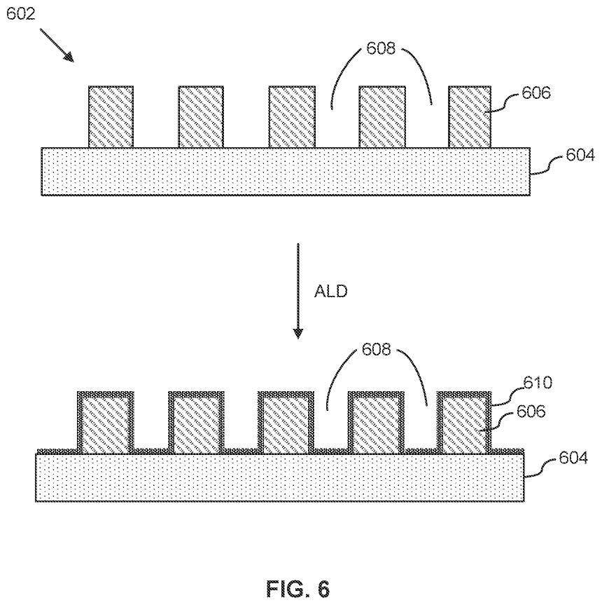

FIG. 6 is a schematic diagram illustrating an example thin film 156 produced by the present thin film deposition system or method. In the illustrated example, the thin film 156 is a TaN barrier layer formed on a semiconductor structure 602 using an ALD process by supplying PDMAT and ammonia vapor sources in a sequential and alternating manner according to some embodiments of the present disclosure. The semiconductor structure 602 includes, among other components, a semiconductor substrate 604 and an oxide layer (sometimes also referred to as an “intra-metal dielectric layer”) 606 formed on the semiconductor substrate. The oxide layer 606 is patterned and etched to form multiple trenches 608.

A thin film 610 (e.g., a TaN barrier layer) is formed on the semiconductor structure 602. The thin film 610 is formed on the bottom surface and the side walls of each of the multiple trenches 608, as shown in FIG. 6. Due to particle prevention mechanisms achieved by the present ALD system, the thin film 610 has a lower particle concentration. In one example, the thickness of the thin film 610 ranges from 0.5 nm to 1 nm.

In one example, the thin film 610 is a TaN barrier layer, which may be useful in the barrier/seed process. A seed layer (e.g., a Cu seed layer) is subsequently deposited on top of the TaN barrier layer. A conductive layer, such as a Cu layer, is subsequently formed using, for example, electro chemical plating (ECP). The excessive portion of the conductive layer outside the trenches 608 is removed using, for example, chemical-mechanical polishing (CMP). The TaN barrier layer prevents the conductive layer from penetrating into the oxide layer 606, whereas the seed layer facilitates the forming of the conductive layer. The improved coverage and thickness uniformity of the TaN barrier layer could provide better protection against copper diffusing into the oxide layer 606.

### SUMMARY

In accordance with some aspects of the disclosure, a thin film deposition system is provided. The thin film deposition system includes: a deposition chamber; a precursor source container containing a precursor source; and a precursor conduit. The precursor conduit is elongated and extends between a proximate end and a distal end, and the proximate end is coupled to an outlet of the precursor source container, and the distal end is coupled to an inlet of the deposition chamber.

In accordance with some aspects of the disclosure, a method for operating a thin film deposition system is provided. The method includes: introducing a carrier gas into a precursor source container; heating the precursor source container to evaporate a precursor source to form a precursor vapor comprising a mixture of the carrier gas and the evaporated precursor source; and delivering the precursor vapor to a deposition chamber through a precursor conduit, wherein the precursor conduit is elongated and extends between a proximate end and a distal end, and wherein the proximate end is coupled to an outlet of the precursor source container, and the distal end is coupled to an inlet of the deposition chamber.

In accordance with some aspects of the disclosure, a thin film deposition system is provided. The thin film deposition system includes: a deposition chamber; a precursor source container containing a precursor source; a precursor conduit coupled between the precursor source container and the deposition chamber; and a primary valve installed at the precursor conduit, wherein the primary valve is switched off when a semiconductor fabrication process performed in the deposition chamber is completed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A thin film deposition system, comprising:
a deposition chamber;
a precursor source container containing a precursor source; and
a precursor conduit, wherein the precursor conduit is elongated and extends between a proximate end and a distal end, and wherein the proximate end is coupled to an outlet of the precursor source container, and the distal end is coupled to an inlet of the deposition chamber.

2. The thin film deposition system of claim 1, wherein the precursor conduit extends horizontally.

3. The thin film deposition system of claim 1, wherein the precursor conduit extends substantially horizontally.

4. The thin film deposition system of claim 2 further comprising:
a primary valve installed at the precursor conduit, wherein the primary valve is switched off when a semiconductor fabrication process performed in the deposition chamber is completed.

5. The thin film deposition system of claim 4, wherein the semiconductor fabrication process is an atomic layer deposition (ALD) process.

6. The thin film deposition system of claim 4, wherein the primary valve is a solenoid valve.

7. The thin film deposition system of claim 4, further comprising:
a first pressure sensor configured to measure a first pressure at an upstream side of the primary valve; and
a second pressure sensor configured to measure a second pressure at a downstream side of the primary valve; and
wherein the primary valve is switched off when the second pressure is higher than the first pressure.

8. The thin film deposition system of claim 4, further comprising:
a supplemental carrier gas conduit coupled to the precursor conduit, wherein supplemental carrier gas is delivered to the precursor conduit through the supplemental carrier gas conduit.

9. The thin film deposition system of claim 8, wherein a pressure of the supplemental carrier gas in the supplemental carrier gas conduit is higher than an atmosphere (atm).

10. The thin film deposition system of claim 9, further comprising:
a carrier gas source configured to provide a carrier gas; and
a mass flow controller in gas communication with the carrier gas source and the precursor source container; and
wherein the mass flow controller is further coupled to the supplemental carrier gas conduit and configured to adjust the pressure of the supplemental carrier gas in the supplemental carrier gas conduit.

11. The thin film deposition system of claim 9, further comprising:
a compressor configured to increase the pressure of the supplemental carrier gas in the supplemental carrier gas conduit.

12. A method for operating a thin film deposition system, the method comprising:
introducing a carrier gas into a precursor source container;
heating the precursor source container to evaporate a precursor source to form a precursor vapor comprising a mixture of the carrier gas and the evaporated precursor source; and
delivering the precursor vapor to a deposition chamber through a precursor conduit, wherein the precursor conduit is elongated and extends between a proximate end and a distal end, and wherein the proximate end is coupled to an outlet of the precursor source container, and the distal end is coupled to an inlet of the deposition chamber.

13. The method of claim 12, further comprising:
depositing a layer resulting from the precursor source on a substrate in the deposition chamber.

14. The method of claim 13, further comprising:
switching off a primary valve installed at the precursor conduit after the depositing is completed.

15. The method of claim 14, further comprising:
measuring a first pressure at an upstream side of the primary valve; and
measuring a second pressure at a downstream side of the primary valve, wherein the switching off is performed when the second pressure is higher than the first pressure.

16. The method of claim 12, further comprising:
introducing a supplemental carrier gas to the precursor conduit through a supplemental carrier gas conduit coupled to the precursor conduit.

17. The method of claim 16, further comprising:
increasing a pressure of the supplemental carrier gas.

18. A thin film deposition system, comprising:
a deposition chamber;
a precursor source container containing a precursor source;
a precursor conduit coupled between the precursor source container and the deposition chamber; and
a primary valve installed at the precursor conduit, wherein the primary valve is switched off when a semiconductor fabrication process performed in the deposition chamber is completed.

19. The thin film deposition system of claim 18, wherein the precursor conduit is elongated and extends substantially horizontally between a proximate end and a distal end, and wherein the proximate end is coupled to an outlet of the precursor source container, and the distal end is coupled to an inlet of the deposition chamber.

20. The thin film deposition system of claim 18, wherein the precursor source includes pentakis(DiMethylAmido)Tantalum (V) (PDMAT).
